(19) United States
(12) Patent Application Publication
(10) Pub. No.: US 2020/0194619 A1
(43) Pub. Date: Jun. 18, 2020

(54) SEMICONDUCTOR DEVICES WITH SUPERLATTICE LAYERS

(71) Applicant: Saphlux, Inc., Branford, CT (US)

(72) Inventors: Joo Won Choi, Branford, CT (US); Jie Song, Branford, CT (US); Chen Chen, Branford, CT (US)

(21) Appl. No.: 16/714,210

(22) Filed: Dec. 13, 2019

Related U.S. Application Data
(60) Provisional application No. 62/779,452, filed on Dec. 13, 2018.

(51) Int. Cl. H01L 33/06; H01L 33/00; H01L 33/32

(52) U.S. Cl. CPC H01L 33/06; H01L 33/32; H01L 33/0075

(57) ABSTRACT

In accordance with some embodiments of the present disclosure, a semiconductor device (e.g., a light-emitting device) is provided. The semiconductor device may include a first epitaxial layer of a first group III-V material, a superlattice layer grown on the first epitaxial layer of the first group III-V material, and a second epitaxial layer of the first group iii-v material grown on the superlattice layer. In some embodiments, the superlattice layer may include the first group III-V material and a second group III-V material. In some embodiments, the first epitaxial layer may include the first group III-V material of a semipolar orientation. The semipolar orientation may include at least one of at least one of a (2021) orientation, a (2021) orientation, a (3031) orientation, or a (3031) orientation including off-axis orientations within ±4 degrees. The second epitaxial layer may include the first group III-V material of the semipolar orientation.

### CROSS REFERENCE TO RELATED APPLICATION

This application claims the benefit of U.S. Provisional Patent Application No. 62/779,452, filed Dec. 13, 2018, which is hereby incorporated by reference herein in its entirety.

### TECHNICAL FIELD

The implementations of the disclosure relate generally to fabrication of semiconductor devices and, more specifically, to semiconductor devices with superlattice layers of group III-V materials.

### BACKGROUND

Group III-V materials (e.g., AlN, GaN, and InN) are suitable materials for fabrication of a variety of semiconductor devices. For example, gallium nitride (GaN) and other III-nitride materials have relatively wide band gaps and can be used to make electro-optic devices (e.g., light-emitting diodes (LEDs), laser diodes (LDs), etc.) that emit radiation in the green and blue regions of the visible spectrum. Group III nitride materials can also be used to fabricate high-power electronics because they exhibit higher breakdown voltages when used for fabricating integrated transistors.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with some embodiments of the present disclosure, a semiconductor device (e.g., a light-emitting device) is provided. The semiconductor device may include a first epitaxial layer of a first group III-V material, a superlattice layer grown on the first epitaxial layer of the first group III-V material, and a second epitaxial layer of the first group iii-v material grown on the superlattice layer. In some embodiments, the superlattice layer may include the first group III-V material and a second group III-V material.

In some embodiments, the first group III-V material may include GaN, and where the second group III-V material may include AlGaN. The first epitaxial layer may include a first undoped layer of the first group III-V material. The second epitaxial layer may include a second undoped layer of the first group III-V material. In some embodiments, the superlattice layer may include a plurality of pairs of a layer of the first group III-V material and a layer of the second group III-V material. A thickness of the plurality of pairs of the layer of the first group III-V material and the layer of the second group iii-v material may be between 0.5 nm and 5 μm.

In some embodiments, the first epitaxial layer may include the first group III-V material of a semipolar orientation. The semipolar orientation may include at least one of at least one of a (2021) orientation, a (2021) orientation, a (3031) orientation, or a (3031) orientation including off-axis orientations within ±4 degrees. The second epitaxial layer may include the first group III-V material of the semipolar orientation.

In some embodiments, the first epitaxial layer of the first group III-V material is grown on a growth template including the first group iii-v material of the semipolar orientation.

In some embodiments, the semiconductor device may include a semiconductor structure grown on the second epitaxial layer of the first group III-V material, the semiconductor structure may include: an active layer may include at least one quantum well structure; and a p-doped layer of the first group III-V material.

In accordance with some embodiments of the present disclosure, a method for fabricating the semiconductor device is provided. The method may include grow the first epitaxial layer of the first group III-V material. The method also include growing, on the first epitaxial layer of the first group III-V material, a superlattice layer grown including the first group iii-v material and a second group III-V material. The method may also include growing, on the superlattice layer, a second epitaxial layer of the first group III-V material.

In some embodiments, growing the first epitaxial layer may include growing a first undoped layer of the first group III-V material. Growing the second epitaxial layer may include growing a second undoped layer of the first group III-V material.

In some embodiments, growing the superlattice layer may include growing a plurality of pairs of a layer of the first group III-V material and a layer of the second group III-V material.

In some embodiments, growing the second epitaxial layer may include growing the group III-V material along the semipolar orientation. In some embodiments, growing the semiconductor structure may include growing an active layer may include at least one quantum well structure; and growing the p-doped layer of the first group III-V material.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIGS. 1A-1C illustrate structures associated with a process for producing group III-nitride substrates in accordance with some embodiments of the present disclosure.

FIG. 2A depicts an example of a semiconductor device according to an implementation of the disclosure.

FIG. 2B depicts an example of a superlattice layer according to an implementation of the disclosure.

FIG. 2C depicts an example of a semiconductor device according to another implementation of the disclosure.

FIGS. 3A and 3B show cathodoluminescence images of semiconductor devices fabricated in accordance with some embodiments of the present disclosure.

FIG. 4 depicts a schematic diagram illustrating an example of a semiconductor device including a semiconductor structure in accordance with some embodiments of the present disclosure.

FIG. 5 illustrates characteristics of example semipolar or nonpolar light-emitting devices in accordance with some embodiments of the present disclosure.

FIG. 6 is a flow diagram illustrating a method for fabricating a semiconductor device in accordance with some embodiments of the present disclosure.

### DETAILED DESCRIPTION

Aspects of the disclosure provide for mechanisms for fabricating light-emitting devices on group III-nitride substrates with nonpolar or semipolar orientations. Examples of the semipolar orientations may include orientations with Miller indices of (2021), (2021), (3031), (3031), (1011), (1122), etc. Examples of the nonpolar orientations may include orientations with Miller indices of (1120), (1010), etc. The group III-nitride substrates may be free of and/or substantially free of stacking faults. The group III-nitride substrates may be fabricated on foreign substrates (e.g., sapphire substrates).

A group-III nitride substrate (e.g., a GaN substrate) produced in accordance with the present disclosure may be free of stacking faults and may have a large area suitable for fabrication of semiconductor devices. The group III-nitride substrate may have any suitable orientation, such as a semipolar orientation or a nonpolar orientation.

In some embodiments, the mechanisms according to the present disclosure may provide a growth template for fabrication of the group III-nitride substrate. The growth template may include a semiconductor layer of a group III-nitride material. The semiconductor layer may be formed on a foreign substrate (e.g., a sapphire substrate) using any suitable epitaxial growth technique. In some embodiments, the semiconductor layer may be formed by growing the group III-nitride material in a particular semipolar or nonpolar orientation utilizing an orientation-controlled epitaxy process.

The mechanisms can grow a layer of semipolar or nonpolar group III-nitride materials on the growth template. For example, an epitaxial layer of the group III-nitride material can be formed on the growth template utilizing any suitable epitaxial growth techniques, such as a hydride vapor phase epitaxy (HVPE) process, a molecular beam epitaxy (MBE) process, a metalorganic chemical vapor deposition (MOCVD) process, etc. In some embodiments, the mechanisms can separate the layer of the semipolar or nonpolar group III-nitride material from the growth template to produce the group III-nitride substrate.

The mechanisms may fabricate a semipolar or nonpolar light-emitting device on the group III-nitride substrate. The semipolar or nonpolar light-emitting device can emit light with a peak emission wavelength between 380 nanometers (nm) and 590 nm. For example, the light may be and/or include blue light (e.g., light with wavelengths between 450 nm and 495 nm), green light (e.g., light with wavelengths between 495 nm and 570 nm), yellow light (e.g., light with wavelengths between 570 nm and 590 nm), etc.

As referred to herein, “light-emitting device” may refer to any device that is capable of emitting light. Examples of the light-emitting device may include light-emitting diodes (LEDs), laser diodes (LDs), etc.

In some embodiments, a semiconductor device may be fabricated on the growth template and/or the group III-nitride substrate. The semiconductor device may be and/or include a light-emitting device and/or any other suitable device including semiconductor materials. As an example, a first epitaxial layer of a first group III-V material (e.g., GaN) may be grown on the growth template and/or the group III-nitride substrate. The first group III-V material may be grown using any suitable epitaxial growth techniques, such as an HVPE process, an MBE process, an MOCVD process, etc. In some embodiments, the first epitaxial layer may be an undoped layer of the first group III-V material that is not intentionally doped with impurities. The first epitaxial layer of the first group III-V material may be grown on the growth template and/or the group III-nitride substrate along a certain semipolar orientation (also referred to as the “first semipolar orientation”) or a certain nonpolar orientation (also referred to as the “first nonpolar orientation”). The first epitaxial layer of the group III-nitride material may be formed on a surface of the group III-nitride substrate that is parallel to and/or approximately parallel to a semipolar plane of the first semipolar orientation (also referred to as the “first semipolar plane”) or a nonpolar plane of the first nonpolar orientation (also referred to as the first “nonpolar plane”).

A superlattice layer may be grown on the first epitaxial layer of the first group III-V material. The superlattice layer may be and/or include a periodic structure of layers of two or more materials. For example, the superlattice layer may include a periodic structure of layers of the first group III-V material and a second group III-V material. The second group III-V material may be AlGaN (e.g., AlₓGa₁₋ₓN, where 0.001≤x≤1) in some embodiments. The superlattice layer may include one or more pairs of a GaN layer and an AlGaN layer. A thickness of one or more pairs of the GaN layer and the AlGaN layer may be between 0.5 nm and 5 micrometers (μm). In some embodiments, a thickness of a layer of the second group III-V material of the superlattice layer or a pair of the GaN layer and the AlGaN layer may be between 0.5 nm and 20 nm (e.g., 0.5 nm≤y≤20 nm, wherein y represents the thickness of the layer of the second group III-V material).

A second epitaxial layer of the first group III-V material may be grown on the superlattice layer. The second epitaxial layer may be an undoped layer of the first group III-V material that is not intentionally doped with impurities.

In some embodiments, a semiconductor structure comprising one or more layers of semiconductor materials and/or any other suitable materials may be fabricated on the second epitaxial layer of the first group III-V material to produce a light-emitting device or any other suitable semiconductor device. For example, one or more epitaxial layers of the first group III-V material may be grown on the second epitaxial layer along the first semipolar orientation or the first nonpolar orientation. The epitaxial layers of the first group III-V material may include an n-doped GaN layer and a p-doped GaN layer. The semiconductor structure may include an active layer including one or more quantum well structures for emitting light. Each of the quantum well structures may include one or more single quantum wells and/or multiple quantum wells. The active layer may be formed on a surface of the first semiconductor layer that is parallel to and/or approximately parallel to the first semipolar plane or the first nonpolar plane.

By growing LEDs along a semipolar or nonpolar that can effectively reduce or eliminate the internal electric fields, the mechanisms disclosed herein can provide high-efficiency and high-brightness light-emitting devices that overcome the efficiency droop, QCSE, and other issues of the conventional LEDs. The light-emitting devices fabricated in accordance with the present disclosure may be used for lighting applications, display applications, wireless communication applications (e.g., optical transmitters), etc.

As referred to herein, a group III material may be any material that includes an element in the boron group, such as gallium (Ga), indium (In), thallium (Tl), aluminum (Al), and boron (B). A group III-nitride material may be any nitride material containing one or more group III materials, such as gallium nitride, aluminum nitride (AlN), aluminum gallium nitride (AlGaN), indium nitride (InN), indium gallium nitride (InGaN), etc. A group V material may be any material that includes an element in the nitrogen group, such as nitrogen (N), phosphorus (P), arsenic (As), etc. A group V material may be any material that includes an element in the nitrogen group, such as nitrogen (N), phosphorus (P), arsenic (As), etc. A group III-V material may be any material that includes a group III element and a group V element, such as aluminum nitride (AlN), gallium nitride (GaN), and indium nitride (InN).

As referred to herein, a semipolar plane may be a crystallographic plane oriented in a semipolar direction. The semipolar direction may be, for example, orientations with Miller indices of (2021), (2021), (3031), (3031), (1011), (1122), etc. A nonpolar plane may be a crystallographic plane oriented in a nonpolar direction. The nonpolar direction may be, for example, orientations with Miller indices of (1120), (1010), etc.

Examples of embodiments of the present disclosure will be described in more detail with reference to the accompanying drawings. It should be understood that the following embodiments are given by way of illustration only to provide a thorough understanding of the disclosure to those skilled in the art. Therefore, the present disclosure is not limited to the following embodiments and may be embodied in different ways. Further, it should be noted that the drawings are not to precise scale and some of the dimensions, such as width, length, thickness, and the like, can be exaggerated for clarity of description in the drawings. Like components are denoted by like reference numerals throughout the specification. Although discussed below primarily in reference to III-nitride materials, the mechanisms disclosed herein may be applied to other group III-V materials within the scope of the present disclosure.

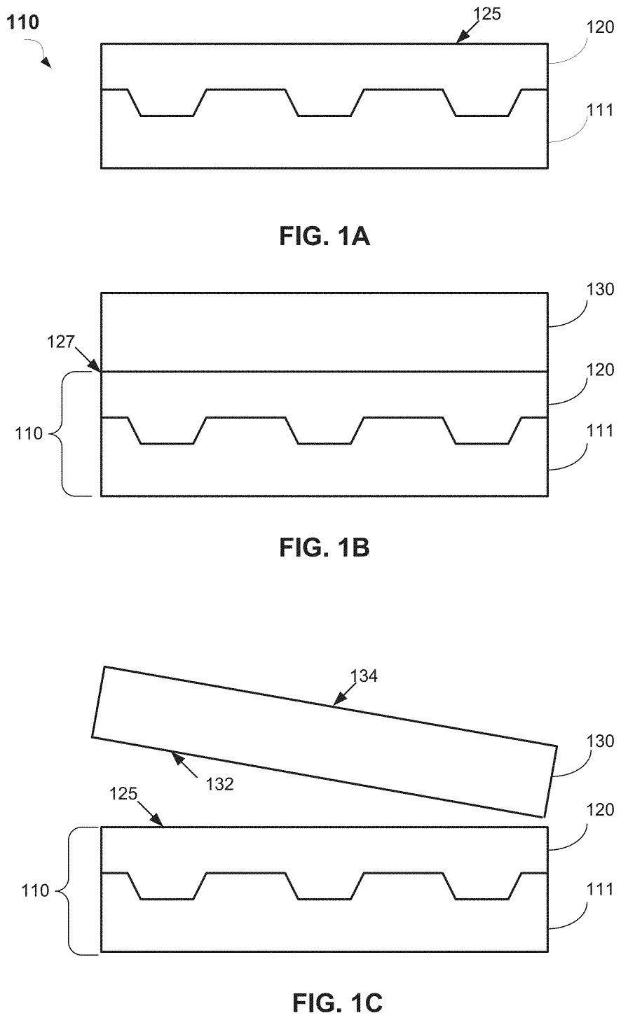

FIGS. 1A-1C illustrate structures associated with a process for producing group III-nitride substrates in accordance with some embodiments of the present disclosure.

Turning to FIG. 1A, a growth template 110 may be provided. Growth template 110 may include one or more layers and may include any suitable material for growing a group III-nitride material (e.g., gallium nitride). For example, growth template 110 may include a substrate 111 and a semiconductor layer 120. The semiconductor layer 120 and the substrate 111 may or may not include different materials. In some embodiments, the substrate 111 may be a foreign substrate containing a material that is not contained in the semiconductor layer 120. For example, the semiconductor layer 120 may include an epitaxial layer of a group III-nitride material (e.g., gallium nitride). The substrate 111 may contain any other suitable crystalline material that can be used to grow the group III-nitride material, such as sapphire, silicon carbide (SiC), silicon (Si), quartz, gallium arsenide (GaAs), aluminum nitride (AlN), etc. The substrate 111 may have any suitable size and/or shape for the growth of group III-nitride materials. In some embodiments, the substrate 111 may be a large-area substrate (e.g., a substrate of a diameter that is equal to or greater than 2 inches).

The semiconductor layer 120 may contain one or more group III-nitride materials having any suitable crystallographic orientation, such as a nonpolar orientation or a semipolar orientation. Examples of the semipolar orientation may include (2021), (1011), (1122), etc. Examples of the nonpolar orientation may include (1120), (1010), etc. The semiconductor layer 120 may be free of and/or substantially free of stacking-faults. As referred to herein, a layer of a group III-nitride material may be regarded as being substantially free of stacking faults when the density of stacking faults in the layer of the group III-nitride material is not greater than a threshold.

While one layer of the semiconductor layer 120 is depicted in FIG. 1A, this is merely illustrative. The semiconductor layer 120 may include any suitable number of layers of group III-nitride materials and/or any other suitable crystalline material. In some embodiments, one or more other layers of crystalline materials (not shown) may be deposited between the substrate 111 and the semiconductor layer 120.

In some embodiments, the semiconductor layer 120 may include one or more surfaces exposing a crystallographic plane with a desired crystallographic orientation (e.g., a semipolar orientation or a nonpolar orientation). For example, a surface 125 of the semiconductor layer 120 may expose a semipolar plane or a nonpolar plane. The surface 125 may be parallel to or approximately parallel to a crystallographic plane with a desired semipolar orientation or a nonpolar orientation. The surface 125 is also referred to herein as the “process surface” of the semiconductor layer 120 and/or the growth template 110.

The substrate 111 may be and/or include a planar substrate, a patterned substrate, etc. In some embodiments, the substrate 111 may be and/or include a patterned substrate having an array of surface structures (e.g., ribs separated by trenches) patterned across a surface of the substrate 111. The surface structures may include a plurality of planar and/or approximately planar surfaces (also referred to herein as the “planar surfaces”). One or more of the planar surfaces may be covered by a masking material that may prevent crystal growth of one or more group III-nitride materials. One or more of the planar surfaces are not covered by the masking material and may initiate epitaxial growth of a group III-nitride material (also referred to as the “crystal-growth surfaces”). In some embodiments, each of the crystal-growth surfaces may be parallel to or approximately parallel (e.g., within 10 mrad) to a particular crystallographic plane (e.g., a c-plane) of the substrate 111.

In some embodiments, the semiconductor layer 120 may be formed by growing one or more group III-nitride materials on the substrate 111 utilizing an orientation-controlled epitaxy process. For example, group III-nitride crystals may be grown with a selected crystallographic plane in a direction that is parallel to the crystal-growth surfaces of the substrate 111. The selected crystallographic plane may be, for example, a semipolar plane or a nonpolar plane (e.g., a (2021) plane for gallium-polar semipolar, a (2021) plane for nitrogen-polar semipolar). In some embodiments, the group III-nitride crystals may be grown from the crystal growth surfaces at distinct locations. The growth of the group III-nitride crystals may continue until the group III-nitride material coalesces above the patterned features on the substrate 111 and forms a continuous epitaxial layer. In some embodiments, one or more buffer layers may be formed on the substrate 111 prior to the growth of the epitaxial layer of the group III-nitride material.

Turning to FIG. 1B, an epitaxial layer 130 of the group III-nitride material may be formed on the growth template 110. The epitaxial layer 130 may be formed by growing the III-nitride material using any suitable epitaxial growth process, such as hydride vapor phase epitaxy (HVPE), molecular beam epitaxy (MBE), metalorganic chemical vapor deposition (MOCVD), etc. For example, the epitaxial layer 130 may be formed by growing an epitaxial layer of the group III-nitride material (e.g., GaN) in an HVPE reactor with suitable growth conditions (e.g., a suitable growth temperature, a suitable growth pressure, a suitable growth rate, etc.). The growth temperature of the epitaxial layer 130 may be, for example, a temperature of around 900 to 1100° C. The pressure for the growth of the epitaxial layer 130 may be, for example, between 50 to 500 mbar. The growth rate of epitaxial layer 130 may be, for example, between 1 to 200 μm/h.

The epitaxial layer 130 may be grown at a suitable growth rate for a certain time period to deposit an epitaxial layer of a desired thickness. The epitaxial layer 130 may have any suitable thickness, such as a thickness between 100 microns and 1 centimeter. In some embodiments, the thickness of the layer 130 may be greater than 100 microns. In some embodiments, the thickness of the layer 130 may be greater than 4000 microns. In some embodiments, the thickness of the epitaxial layer 130 can be greater than the thickness of layer 120. The size of the epitaxial layer 130 (e.g., a diameter of the epitaxial layer 130) may be the same as or substantially the same as the size of the substrate 111 and/or the growth template 110 (e.g., a diameter of the substrate 111 and/or the growth template 110). In some embodiments, a diameter of layer 130 may be 2 inches, 4 inches, 6 inches, and/or any other suitable value. In some embodiments, the diameter of the epitaxial layer 130 may be equal to or greater than 2 inches.

As illustrated in FIG. 1C, the epitaxial layer 130 may be separated from the growth template 110. In some embodiments, the epitaxial layer 130 may be separated from the growth template 110 along a longitudinal direction of the growth template 110. The longitudinal direction of the growth template 110 may be parallel to and/or approximately parallel to the process surface of the growth template 110.

In some embodiments, the epitaxial layer 130 may be separated from the growth template 110 along an interface 127 between the growth template 110 and the semiconductor layer 120. The interface may be defined by the surface 125 of the growth template 110 and a surface 132 of the epitaxial layer 130. The surface 125 and the surface 132 may or may not contact with each other. In some embodiments, one or more portions of the surface 125 contact with one or more portions of the surface 132. The interface may be parallel to or approximately parallel to the longitudinal direction of the growth template 110.

The separation of the semiconductor layer 120 from the growth template 110 may be achieved using any suitable technique or combination of techniques. For example, the epitaxial layer 130 may be separated from the growth template 100 using a wire saw (e.g., by slicing the interface or a portion of the epitaxial layer 130 along the longitudinal direction of the growth template 110). As another example, the layer 120 may be separated from the growth template 110 by laser lift-off and/or chemical lift-off.

In some embodiments, a semiconductor layer (not shown) including air voids may be formed between the growth template and the epitaxial layer 130 (also referred to as the “sacrificial layer”). In some embodiments, the sacrificial layer may be regarded as being part of the growth template 110. The epitaxial layer 130 may be separated from the growth template 110 via the sacrificial layer. For example, the epitaxial layer 130 can be separated from the growth template 110 by application of physical force to the sacrificial layer. As another example, the epitaxial layer 130 can be separated from the sacrificial layer by chemical etching. In some embodiments, after separation of the epitaxial layer 130 from the growth template 110, the sacrificial layer can remain on the growth template 110.

Upon separation from the growth template 110, the epitaxial layer 130 may then be used as a free-standing group III-nitride substrate. The free-standing group III-nitride may have a wurtzite structure and may have a nonpolar or semipolar orientation. Each of the surfaces 132 and 134 of the epitaxial layer 130 and/or the group III-nitride substrate may be a continuous planar surface. The surfaces 132 and/or 134 may be parallel to or approximately parallel to a desired crystallographic plane of the group III-nitride material, such as a semipolar plane or a nonpolar plane. In some embodiments, the surfaces 132 and/or 134 may expose a single semipolar plane or a single nonpolar plane of the group III-nitride material.

The epitaxial layer 130 may be free of or substantially free of stacking faults. As referred to herein, an epitaxial layer of a group III-nitride material may be regarded as being substantially free of stacking faults when the density of stacking faults in the epitaxial layer of the group III-nitride material is not greater than a threshold. A device manufacturing process can be performed on the free-standing group III-nitride substrate to form LEDs and/or any other desired semiconductor device.

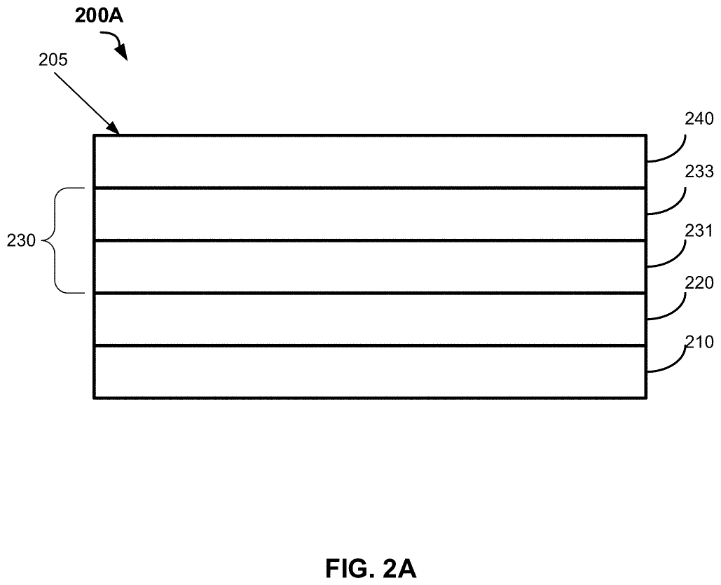

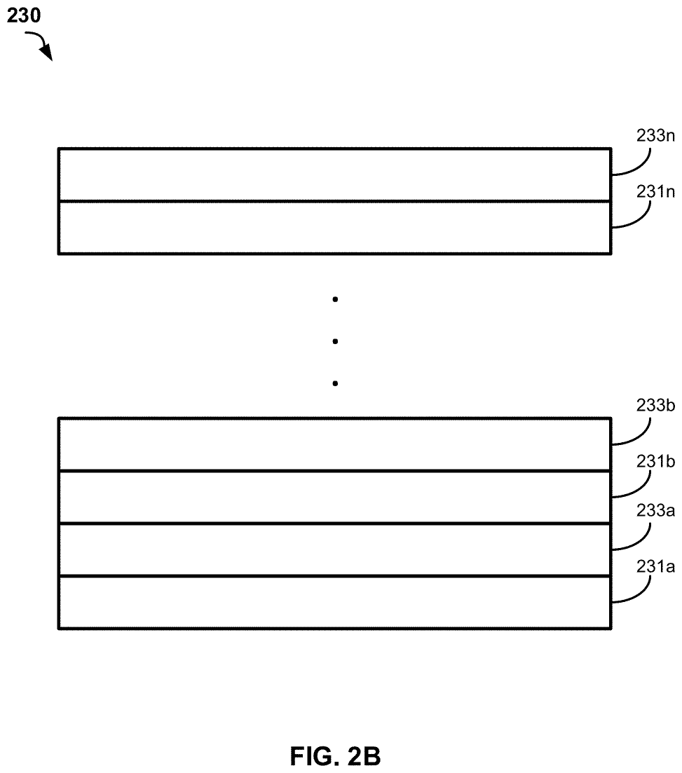

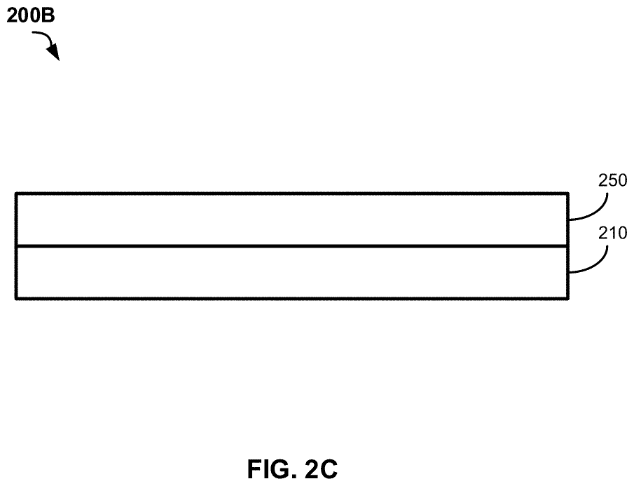

Referring to FIG. 2A, an example 200A of a semiconductor device in accordance with some embodiments of the present disclosure is shown.

As illustrated, the semiconductor device 200A may be grown on a growth template 210. The growth template 210 may be and/or include a semipolar or nonpolar group III-nitride substrate. The growth template 210 may contain a group III-nitride material (e.g., GaN) having a semipolar orientation (also referred to as the “first semipolar orientation”) or a nonpolar orientation (also referred to as the “first nonpolar orientation”). The first semipolar orientation may be, for example, an orientation with Miller indices of (2021), (2021), (3031), (3031), (1011), (1122), or (1122) (including off-axis orientations within ±4 and/or ±2 degrees). In some embodiments, the first semipolar orientation may be within about 4 degrees of at least one of a (2021) orientation, a (2021) orientation, a (3031) orientation, or a (3031) orientation. The first nonpolar orientation may be, for example, an orientation with Miller indices of (1120) or (1010) (including off-axis orientations within ±4 and/or ±2 degrees).

In some embodiments, the semipolar or nonpolar group III-nitride substrate may be free of and/or substantially free of stacking faults. The semipolar or nonpolar group III-nitride substrate may be a bulk substrate that has a diameter equal to or greater than 2 inches. In one implementation, the growth template 210 may include a group III-nitride substrate formed on a foreign substrate (e.g., a sapphire substrate). The growth template 210 may be and/or include, for example, the growth template 110 and/or the epitaxial layer 130 of FIGS. 1A-1C.

An epitaxial layer 220 of a first group III-V material may be grown on the growth template 210. The group III-nitride material may be, for example, GaN. The epitaxial layer 220 may be an undoped layer of the first group III-V material (also referred to herein as the “first undoped layer of the first group III-V material”). A thickness of the epitaxial layer 220 may be about 0.1 μm in some embodiments.

A superlattice layer 230 may be grown on the layer 220. The superlattice layer 230 may be and/or include a periodic structure of layers of two or more materials. For example, the superlattice layer 230 may include a periodic structure of layers of the first group III-V material and a second group III-V material. The second group III-V material may be AlGaN (e.g., AlₓGa₁₋ₓN, where 0.001≤x≤1) in some embodiments. As illustrated in FIG. 2A, the superlattice layer 230 may include a pair of a layer of the first group III-V material 231 (e.g., a GaN layer) and a layer of the second group III-V material 233 (e.g., an AlGaN layer).

In some embodiments, the superlattice layer 230 may include a plurality of pairs of layers 231 and 233 (e.g., two or more pairs). For example, as illustrated in FIG. 2B, the superlattice layer 230 may include layers 231a, 231b, . . . , 231n of the first group III-V material. The superlattice layer 230 may also include layers 233a, 233b, . . . , 233n, of the second group III-V material. The layers of the first group III-V material and the layers of the second group III-V material may be stacked alternatively to form the superlattice layer 230. As such, the superlattice layer 230 may include a first pair of a layer 231a of the first group III-V material and a layer 233a of the second group III-V material, a second pair of a layer 231b of the first group III-V material and a layer 233b of the second group III-V material, a pair of a layer 231n of the first group III-V material and a layer 233n of the second group III-V material, etc. The superlattice layer 230 may include any suitable number of pairs of layers of the first group III-V material and the second group III-V material. The superlattice layer 230 may include 10 pairs of AlGaN and GaN layers in some embodiments. A thickness of one or more pairs of the layer 231 and the layer 233 may be between 0.5 nm and 5 μm. In some embodiments, a thickness of the superlattice layer may be between 0.5 nm and 5 μm. In some embodiments, a thickness of the layer 233 and/or a pair of the layer 231 and the layer 233 may be between 0.5 nm and 20 nm (e.g., 0.5 nm≤y≤20 nm, wherein y represents the thickness).

An epitaxial layer 240 of the first group III-V material may be grown on the superlattice layer 230 in some embodiments. The epitaxial layer 240 may be and/or include an undoped layer of the first group III-V material (also referred to herein as the “second undoped layer of the first group III-V material”) and/or a doped layer of the first group III-V material (e.g., a doped GaN layer). The second undoped layer of the first group III-V material may include a u-GaN layer in some embodiments. A thickness of the epitaxial layer 240 may be about 0.5 μm in some embodiments.

Each of the layers 220, 230, 240 may be grown using any suitable epitaxial growth techniques, such as an HVPE process, an MBE process, an MOCVD process, etc. Each of the layers 220, 230, and 240 may include the first group III-V material (e.g., GaN) of a desired semipolar or nonpolar orientation, such as (2021), (2021), (3031), (3031), (1011), (1122), or (1122) (including off-axis orientations within ±4 and/or ±2 degrees). Growing the layers 220, 230, and/or 240 may involve growing the first group III-V material and/or the second group III-V material along the desired semipolar or nonpolar orientation.

In some embodiments, the semiconductor device 200A may be used as a growth template to produce a semipolar or nonpolar light-emitting device and/or any other suitable device.

Referring to FIG. 2C, an example 200B of a semiconductor device in accordance with some embodiments of the present disclosure is illustrated. As shown, the semiconductor device 200B may include an epitaxial layer of the first group III-V material 250 grown on the growth template 210. The epitaxial layer 250 may represent a combination of the layers 220 and 240 (e.g., an undoped layer of GaN of 0.6 μm). As shown, no superlattice layer is grown in the epitaxial layer 250.

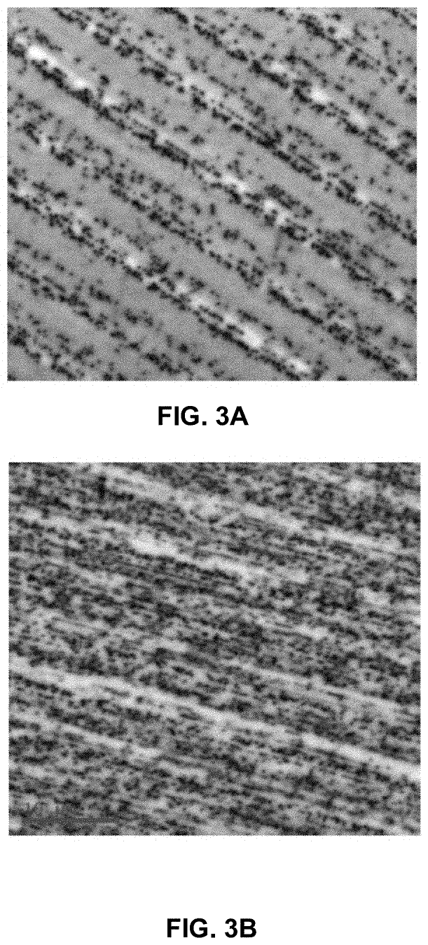

FIGS. 3A and 3B show cathodoluminescence images of semiconductor devices fabricated in accordance with FIGS. 2A and 2C, respectively. Threading dislocations appear as dark spots in FIGS. 3A-3B. As shown, FIG. 3B contain significantly fewer dark spots than FIG. 3A. As such, the insertion of the superlattice layer 230 between layers 220 and 240 can significantly reduce the threading dislocations presented in the semiconductor device.

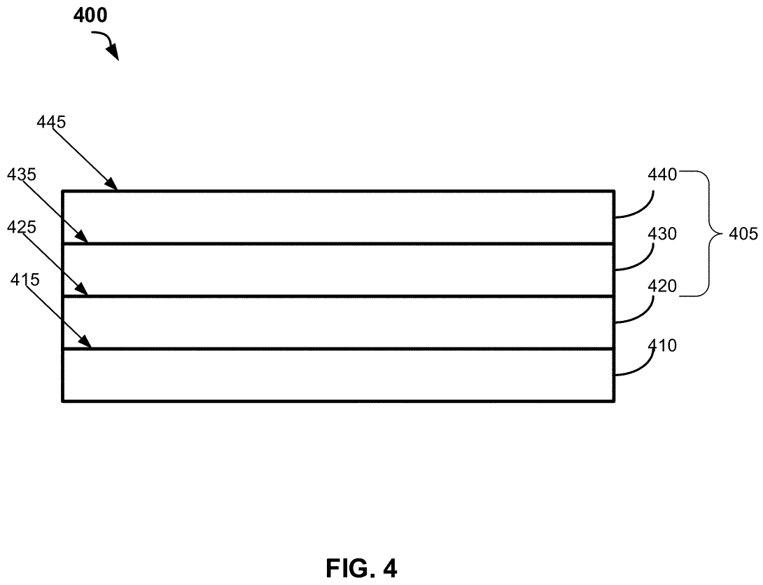

FIG. 4 is a schematic diagram illustrating an example 400 of a semiconductor device in accordance with some embodiments of the present disclosure. As illustrated, semiconductor device 400 may include a substrate 410, a first semiconductor layer 420, a second semiconductor layer 430, and a third semiconductor layer 440. In some embodiments, the semiconductor device 400 may be and/or include a light-emitting device.

The substrate 410 may be and/or include a semipolar or nonpolar group III-nitride substrate. The substrate 410 may contain a group III-nitride material (e.g., GaN) having a semipolar orientation (also referred to as the “first semipolar orientation”) or a nonpolar orientation (also referred to as the “first nonpolar orientation”). The first semipolar orientation may be, for example, an orientation with Miller indices of (2021), (2021), (3031), (3031), (1011), (1122), or (1122) (including off-axis orientations within ±4 degrees). In some embodiments, the first semipolar orientation may be within about 4 degrees of at least one of a (2021) orientation, a (2021) orientation, a (3031) orientation, or a (3031) orientation. The first nonpolar orientation may be, for example, an orientation with Miller indices of (1120) or (1010) (including off-axis orientations within ±4 degrees).

The semipolar or nonpolar group III-nitride substrate may be free of and/or substantially free of stacking faults. The semipolar or nonpolar group III-nitride substrate may be a bulk substrate that has a diameter equal to or greater than 2 inches. In one implementation, the substrate 410 may include a group III-nitride substrate formed on a foreign substrate (e.g., a sapphire substrate). The substrate 410 may be and/or include, for example, the growth template 110, the epitaxial layer 130, and/or the semiconductor device 200A of FIGS. 1A-2A.

A surface 415 of the substrate 410 may expose a semipolar plane (also referred to as the “first semipolar plane”) or a nonpolar plane of the group III-V material (also referred to as the “first nonpolar plane”). The first semipolar plane may be, for example, a (2021) plane, a (2021) plane, a (3031) plane, a (3031) plane, a (1011) plane, a (1122) plane, a (1122) plane, etc. The first nonpolar plane may be, for example, a (1120) plane, a (1010) plane, etc. In some embodiments, the first semipolar plane may be a crystallographic plane oriented in the first semipolar orientation. The first nonpolar plane may be a crystallographic plane oriented in the first nonpolar orientation. The surface 415 may be and/or include surfaces 125, 132, 134, and/or 205 of FIGS. 1A-2A.

One or more layers of semiconductor materials and/or any other material may be grown on the surface 415 of the substrate 410 to fabricate the semiconductor device 400. For example, as shown in FIG. 4, a semiconductor structure 405 may be fabricated on the substrate 410. The semiconductor structure 405 may include the first semiconductor layer 420, the second semiconductor layer 430, the third semiconductor layer 440, and/or any other suitable component for fabricating a semiconductor device in accordance with various embodiments of the present disclosure. Each of the first semiconductor layer 420, the second semiconductor layer 430, and/or the third semiconductor layer 440 may have a desirable semipolar or nonpolar orientation, such as the first semipolar orientation or the first nonpolar orientation. Each of the first semiconductor layer 420, the second semiconductor layer 430, and/or the third semiconductor layer 440 may include one or more surfaces exposing a crystallographic plane with a desired crystallographic orientation (e.g., a semipolar orientation or a nonpolar orientation). The surfaces 425, 435, and/or 445 may be parallel to and/or approximately parallel to the surface 415 and may be parallel to and/or approximately parallel to the first semipolar plane or the first nonpolar plane. In some embodiments, the surface 415 may be free of and/or substantially free of stacking faults. The growth of the first semiconductor layer 420, the second semiconductor layer 430, and/or the third semiconductor layer 440 does not introduce stacking faults. As such, the semiconductor device 400 may be free of and/or substantially free of stacking faults.

The first semiconductor layer 420 may include one or more epitaxial layers of group III-nitride materials and any other suitable semiconductor material. For example, the first semiconductor layer 420 may an epitaxial layer of the group III-nitride material doped with a first conductive type impurity (e.g., a Si-doped GaN layer, a Ge-doped GaN layer). The first conductive type impurity may be an n-type impurity in some embodiments. The first semiconductor layer 420 may contain the group III-nitride material having the first semipolar orientation or the first nonpolar orientation.

The second semiconductor layer 430 may include one or more layers of semiconductor materials and/or any other suitable material for emitting light. For example, the semiconductor layer 430 may include an active layer comprising one or more quantum well structures for emitting light. Each of the quantum well structures may be and/or include a single quantum well structure (SQW) and/or a multi-quantum well (MQW) structure. Each of the quantum well structures may include one or more quantum well layers and barrier layers (not shown in FIG. 3). The quantum well layers and barrier layers may be alternately stacked on one another. The quantum well layers may comprise indium (e.g., indium gallium nitride). Each of the quantum well layers may be an undoped layer of indium gallium nitride (InGaN) that is not intentionally doped with impurities. Each of the barrier layers may be an undoped layer of the group III-nitride material that is not intentionally doped with impurities. A pair of a barrier layer (e.g., a GaN layer) and a quantum well layer (e.g., an InGaN layer) may be regarded as being a quantum well structure. The second semiconductor layer 430 may contain any suitable number of quantum well structures. For example, the number of the quantum well structures (e.g., the number of pairs of InGaN and GaN layers) may be 3, 4, 5, etc. The active layer and/or the quantum well structures may be formed along the first semipolar direction or the first nonpolar direction.

When energized, the second semiconductor layer 430 may produce light. For example, when an electrical current passes through the active layer, electrons from the first semiconductor layer 420 (e.g., an n-doped GaN layer) may combine in the active layer with holes from the third semiconductor layer 440 (e.g., a p-doped GaN layer). The combination of the electrons and the holes may generate light. In some embodiments, the light may have a peak emission wavelength between 380 nm and 590 nm. For example, the light may be and/or include blue light (e.g., light with a wavelength between 450 nm and 495 nm), green light (e.g., light with wavelengths between 495 nm and 570 nm), yellow light (e.g., light with wavelengths between 570 nm and 590 nm), etc. In some embodiments, the second semiconductor layer 430 may emit light with wavelengths between 500 nm and 550 nm. In some embodiments, the second semiconductor layer 430 may emit light with wavelength between 400 nm and 550 nm. In some embodiments, the second semiconductor layer 430 may emit light with wavelengths between 495 nm and 575 nm.

The third semiconductor layer 440 may include one or more epitaxial layers of the group III-nitride material and/or any other suitable material. For example, the third semiconductor layer 440 can include an epitaxial layer of the group III-nitride material doped with a second conductive type impurity that is different from the first conductive type impurity. For example, the second conductive type impurity may be a p-type impurity.

While certain layers of semiconductor materials are shown in FIG. 4, this is merely illustrative. For example, one or more intervening layers may or may not be deposited between the substrate 410 and the first semiconductor layer 420. One or more intervening layers may or may not be deposited between two semiconductor layers of FIG. 4 (e.g., between the first semiconductor layer 420 and the second semiconductor layer 430, between the second semiconductor layer 430 and the third semiconductor layer 440, etc.). In one implementation, a first surface of the first semiconductor layer 420 may directly contact with a surface of the substrate 410. The second semiconductor layer 430 may be deposited directly on a second surface of the first semiconductor layer 420. In another implementation, one or more intervening layers (not shown in FIG. 4) may be formed between the first semiconductor layer 420 and the second semiconductor layer 430. Alternatively or additionally, one or more intervening layers (not shown in FIG. 4) may be deposited between the first semiconductor layer 420 and the substrate 410. In some embodiments, the first semiconductor layer 420 may include an undoped layer of the group III-nitride material. In some embodiments, the semiconductor device 400 can include one or more layers of semiconductor materials and/or any other material that are formed on the third semiconductor layer 440.

The semiconductor device 200A and/or 400 can be used to produce light-emitting diodes, laser diodes, transistors, solar cells, and/or any other suitable semiconductor devices. The semiconductor device 200A and/or 400 can be used to implement display applications, lighting applications, data storage applications, power electronic applications, communication applications, etc. In one implementation, a single light-emitting device may be fabricated using the semiconductor device 200A and/or 400. In another implementation, multiple light-emitting devices and/or structures may be fabricated using the semiconductor device 200A and/or 400. As an example, one or more arrays of light-emitting structures may be fabricated on the semiconductor device 200A and/or 400. Each of the light-emitting structures may be a micro-size light-emitting diode (LED) (also referred to as the “micro-LED”). The micro-LED may have dimensions on the scale of micrometers. Each of the arrays may have any suitable number of light-emitting structures. The light-emitting structures may be arranged in one or more rows and/or columns or in any other suitable manner. Multiple arrays of light-emitting structures fabricated on the semiconductor device 200A and/or 400 may or may not have the same number of light-emitting structures.

The semiconductor device 200A and/or 400 may have any suitable dimensions to produce various applications. For example, the semiconductor device 200A and/or 400 may have a certain chip area defined by a first side of the semiconductor device 200A and/or 400 (e.g., a length) and a second side of the semiconductor device 200A and/or 400 (e.g., a width). In one implementation, the semiconductor device 200A and/or 400 may have a small chip area (e.g., a chip area that is equal to and/or smaller than a threshold (e.g., 22,500 μm², 90,000 μm², etc.)). In another implementation, the semiconductor device 200A and/or 400 may have a large chip area (e.g., a chip area that is greater than the threshold. A side of the chip area of the semiconductor device 200A and/or 400 may be less than 700 μm in some embodiments.

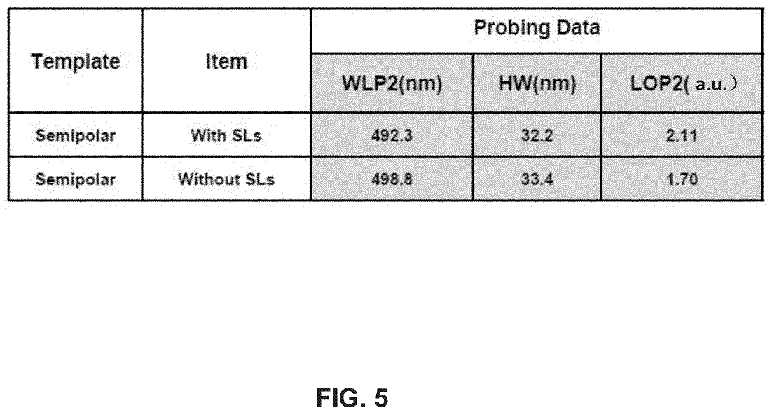

FIG. 5 illustrates characteristics of example semipolar or nonpolar light-emitting devices in accordance with some embodiments of the present disclosure. The semipolar or nonpolar light-emitting devices may be grown on a growth template for growing semipolar or nonpolar group III-V materials as described herein. As shown, a light-emitting device without a superlattice layer may have a peak emission wavelength of about 498.8 nm, an HWHM (Half Width at Half Maximum) of about 33.4 nm, and light-output power (LOP) of 1.7 arbitrary units (a.u.). A light-emitting device including a superlattice layer as described above may have a peak emission wavelength of about 492.3 nm, an HWHM of about 32.2 nm, and light-output power of 2.11 arbitrary units. As such, the light-output power of the light-emitting device with the superlattice layer is significantly higher than the light-output power of the light-emitting device without the superlattice layer. Accordingly, the inclusion of the superlattice layer in the light-emitting device can significantly improve the light-output power of the light-emitting device.

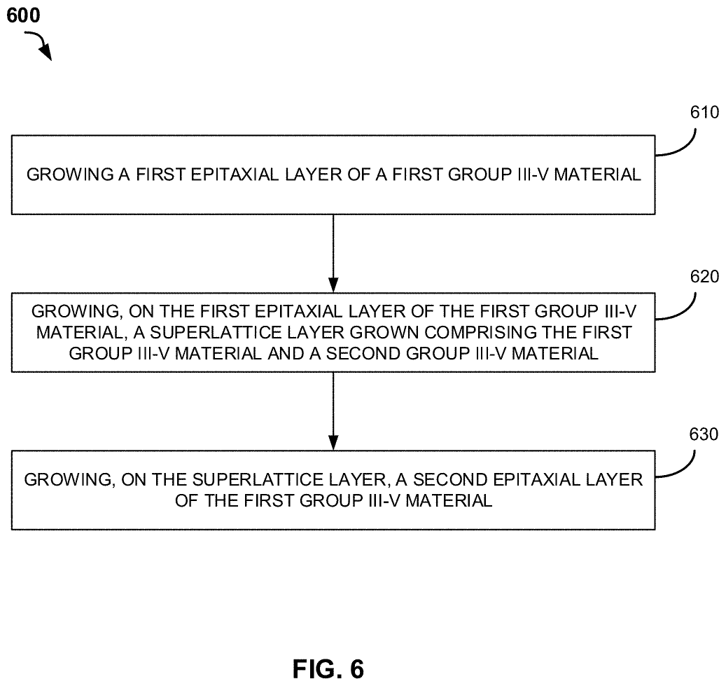

FIG. 6 is a flow diagram illustrating an example 600 of a method for fabricating a semiconductor device according to some embodiments of the disclosure.

At block 610, a first epitaxial layer of a first group III-V material may be grown. The first group III-V material may be, for example, GaN. Growing the first epitaxial layer of the first group III-V material may include growing a first undoped layer of the first group III-V material. In some embodiments, growing the first epitaxial layer of the first group III-V material may include growing the first group III-V material on a growth template (e.g., the growth template 210 as described in connection with FIG. 2A, the substrate as described in connection with FIG. 4). In some embodiments, growing the first epitaxial layer of the first group III-V material may include growing the first group III-V material of a semipolar or nonpolar orientation (e.g., by growing the first group III-V material on a growth template along the semipolar of nonpolar orientation). In some embodiments, the first epitaxial layer of the first group III-V material may be and/or include a epitaxial layer 220 as described in connection with FIG. 2A and may be grown by performing one or more operations described in connection with FIG. 2A.

At block 620, a superlattice layer may be grown on the first epitaxial layer of the first group III-V material. Growing the superlattice layer may include growing a periodic structure of layers of two or more materials. For example, growing the superlattice layer may include growing one or more pairs of a layer of the first group III-V material and a layer of a second group III-V material (e.g., AlGaN). In some embodiments, the superlattice layer may be and/or include a superlattice layer 230 as described in connection with FIGS. 2A-2B and may be grown by performing one or more operations described in connection with FIGS. 2A-2B.

At block 630, a second epitaxial layer of the first group III-V material may be grown on the superlattice layer. In some embodiments, growing the second epitaxial layer of the first group III-V material may include growing a second undoped layer of the first group III-V material. In some embodiments, growing the second epitaxial layer of the first group III-V material may include growing one or more doped layers of the group III-V material. The second epitaxial layer may include, for example, the epitaxial layer 240 as described in connection with FIGS. 2A-2B. In some embodiments, process 600 may further include growing a semiconductor structure on the second epitaxial layer of the first group III-V material. Growing the semiconductor structure may include growing an n-doped layer of the first group III-V material, an active layer comprising one or more quantum well structure for emitting light, a p-doped layer of the first group III-V material, etc. In some embodiments, the semiconductor structure may be and/or include a semiconductor structure 405 of FIG. 4 and may be grown by performing one or more operations described in connection with FIG. 2A

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A semiconductor device, comprising:
a first epitaxial layer of a first group III-V material;
a superlattice layer grown on the first epitaxial layer of the first group III-V material, wherein the superlattice layer comprises the first group III-V material and a second group III-V material; and
a second epitaxial layer of the first group III-V material grown on the superlattice layer.

2. The semiconductor device of claim 1, wherein the first group III-V material comprises GaN, and wherein the second group III-V material comprises AlGaN.

3. The semiconductor device of claim 1, wherein the first epitaxial layer comprises a first undoped layer of the first group III-V material.

4. The semiconductor device of claim 3, wherein the second epitaxial layer comprises a second undoped layer of the first group III-V material.

5. The semiconductor device of claim 1, wherein the superlattice layer comprises a plurality of pairs of a layer of the first group III-V material and a layer of the second group III-V material.

6. The semiconductor device of claim 5, wherein a thickness of the plurality of pairs of the layer of the first group III-V material and the layer of the second group III-V material is between 0.5 nm and 5 μm.

7. The semiconductor device of claim 5, wherein the first epitaxial layer comprises the first group III-V material of a semipolar orientation, wherein the semipolar orientation comprises at least one of a (2021) orientation, a (2021) orientation, a (3031) orientation, or a (3031) orientation including off-axis orientations within ±4 degrees.

8. The semiconductor device of claim 7, wherein the second epitaxial layer comprises the first group III-V material of the semipolar orientation.

9. The semiconductor device of claim 7, wherein the first epitaxial layer of the first group III-V material is grown on a growth template comprising the first group III-V material of the semipolar orientation.

10. The semiconductor device of claim 1, further comprising:
a semiconductor structure grown on the second epitaxial layer of the first group III-V material, the semiconductor structure comprising:
an active layer comprising at least one quantum well structure; and
a p-doped layer of the first group III-V material.

11. A method for fabricating a semiconductor device, comprising:
growing a first epitaxial layer of a first group III-V material;
growing, on the first epitaxial layer of the first group III-V material, a superlattice layer grown comprising the first group III-V material and a second group III-V material; and
growing, on the superlattice layer, a second epitaxial layer of the first group III-V material.

12. The method of claim 11, wherein the first group III-V material comprises GaN, and wherein the second group III-V material comprises AlGaN.

13. The method of claim 11, wherein growing the first epitaxial layer comprises growing a first undoped layer of the first group III-V material.

14. The method of claim 13, wherein growing the second epitaxial layer comprises growing a second undoped layer of the first group III-V material.

15. The method of claim 11, wherein growing the superlattice layer comprises growing a plurality of pairs of a layer of the first group III-V material and a layer of the second group III-V material.

16. The method of claim 15, wherein a thickness of the plurality of pairs of the layer of the first group III-V material and the layer of the second group III-V material is between 0.5 nm and 5 μm.

17. The method of claim 11, wherein growing the first epitaxial layer comprises growing the first group III-V material on a growth template along a semipolar orientation.

18. The method of claim 17, wherein the semipolar orientation comprises at least one of a (2021) orientation, a (2021) orientation, a (3031) orientation, or a (3031) orientation including off-axis orientations within ±4 degrees.

19. The method of claim 18, wherein growing the second epitaxial layer comprises growing the first group III-V material along the semipolar orientation.

20. The method of claim 11, further comprising:
growing a semiconductor structure on the second epitaxial layer of the first group III-V material, wherein growing the semiconductor structure comprises:
growing an active layer comprising at least one quantum well structure; and
growing a p-doped layer of the first group III-V material.
